(19) United States
(12) Patent Application Publication
(10) Pub. No.: US 2007/0103247 A1
(43) Pub. Date: May 10, 2007

(54) PLL TRANSIENT RESPONSE CONTROL SYSTEM AND COMMUNICATION SYSTEM

(75) Inventors: Tetsuro YOKOTA, Kadoma-shi, Osaka (JP); Satoshi YAMAGUCHI, Kadoma-shi, Osaka (JP); Shigeru KATAOKA, Kadoma-shi, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 11/553,607

(22) Filed: Oct. 27, 2006

(30) Foreign Application Priority Data
Oct. 31, 2005 (JP) JP2005-316764

(51) Int. Cl. H03B 5/32

(52) U.S. Cl. 331/158

(57) ABSTRACT

The present invention includes two lines of PLL circuits. The first PLL circuit 31 includes a first voltage-controlled oscillator 34 that increases in oscillation frequency as a control voltage increases. The second PLL circuit 41 includes a second voltage-controlled oscillator 44 that decreases in oscillation frequency as a control voltage increases. A feedback voltage applied to the first voltage-controlled oscillator 34 is added to a feedback voltage applied to the second voltage controlled oscillator 44. The output signals of the two voltage-controlled oscillators 34, 44 are synthesized by a mixer 13, so that the transient responses of the first PLL circuit 31 and the second PLL circuit 41 cancel each other out. Thus, the transient response of the output signal of the mixer 13 becomes shorter.

### BACKGROUND OF THE INVENTION

1. Field of the Invention

The present invention relates to a PLL transient response control system that suppresses a transient response of a PLL circuit used in a communication system such as a portable telephone and reduces a lock-up time of the PLL circuit. The present invention also relates to a communication system including the PLL transient response control system.

2. Description of Related Art

In recent years, with the rapid progress of communication and semiconductor technologies, various communication modes have been proposed and put to practical use in the communication system such as a portable telephone. TDMA (time division multiple access), which is one of the communication modes, divides a single frequency by time into a plurality of channels. In TDMA, however, there is only a very short time interval between communication slots.

To switch the communication slots in a short time, a conventional system has two lines of PLL (phase locked loop) circuits, each of which includes a VCO (voltage-controlled oscillator). While one VCO is used for communications, the other VCO is locked at a frequency required for the next slot, so that the VCO outputs are switched between the communication slots.

Recently, another system has been proposed that uses a single line of a PLL circuit with a fast lock-up time for frequency switching between the communication slots. When the oscillation frequency of the PLL circuit is changed to a different desired frequency, the lock-up time indicates the length of time it takes for the PLL circuit to reach the desired frequency.

FIG. 13 is a block diagram showing a conventional PLL system that includes two lines of PLL circuits.

As shown in FIG. 13, the PLL system includes a crystal oscillator 101, a buffer 102, a counter 103, a mixer 104, a first PLL circuit 110, and a second PLL circuit 120. The first PLL circuit 110 includes a phase comparator (PC) 111, a low-pass filter (LPF) 112, a VCO 113, and a counter 114. The second PLL circuit 120 includes a phase comparator 121, a LPF 122, a VCO 123, and a counter 124.

In FIG. 13, a signal of a reference frequency f_{REF} generated by a reference frequency generator including the crystal oscillator 101 and the buffer 102 is input to the phase comparator 111 of the first PLL circuit 110 and to the counter 103. The signal of the reference frequency f_{REF} is divided down to 50 kHz by the counter 103, and then is input to the phase comparator 121 of the second PLL circuit 120.

In the first PLL circuit 110, the phase comparator 111 compares the reference frequency f_{REF} with a frequency given by the counter 114 and outputs a phase difference signal according to the phase difference between the two frequencies to the LPF 112. The LPF 112 generates a direct-current control signal by integrating the phase difference signal from the phase comparator 111 and outputs the direct-current control signal to the VCO 113. The VCO 113 oscillates based on the direct-current control signal from the LPF 112, and the oscillation frequency f_{VC1} of the VCO 113 is output to the mixer 104 as well as being fed back to the counter 114. The counter 114 divides the oscillation frequency f_{VC1} of the VCO 113 at a predetermined division ratio N1 and outputs the divided frequency to the phase comparator 111. The division ratio of the counter 114 can be set with an external control signal.

In the second PLL circuit 120, the phase comparator 121 compares the reference frequency f_{REF} with a frequency given by the counter 124 and outputs a phase difference signal according to the phase difference between the two frequencies to the LPF 122. The LPF 122 generates a direct-current control signal by integrating the phase difference signal from the phase comparator 121 and outputs the direct-current control signal to the VCO 123. The VCO 123 oscillates based on the direct-current control signal from the LPF 122, and the oscillation frequency f_{VC2} of the VCO 123 is output to the mixer 104 as well as being fed back to the counter 124. The counter 124 divides the oscillation frequency f_{VC2} of the VCO 123 at a predetermined division ratio N2 and outputs the divided frequency to the phase comparator 121. The division ratio of the counter 124 can be set with an external control signal.

The mixer 104 mixes the oscillation frequency f_{VC1} of the VCO 113 and the oscillation frequency f_{VC2} of the VCO 123 and provides an output frequency f_{OUT}.

FIG. 14 shows frequency variations during a transient response of the conventional PLL system. In FIG. 14, P21, P22, and P23 represent the frequency variations in the output signals of the VCO 113, the VCO 123, and the mixer 104, respectively.

As represented by P22, the second PLL circuit 120 is in the steady state because the frequency is locked, and thus causes no frequency variation. However, as represented by P21, the oscillation frequency f_{VC1} of the VCO 113 varies due to the transient response when it is changed to a desired frequency.

Such a variation in the oscillation frequency f_{VC1} of the VCO 113 allows the output frequency f_{OUT} of the mixer 104 to vary because of the effect of the oscillation frequency f_{VC1}, as represented by P23.

These frequency variations may occur, e.g., when the base stations are out of synchronization. The out-of-synchronization of the base stations can reduce a transmission rate, since frequency variations caused by the transient response of the first PLL circuit 110 occur at the beginning of a communication slot.

One of the methods for preventing such a low transmission rate is disclosed in Patent Document 1 (Japanese Patent No. 3248453). In a configuration of Patent Document 1, the frequencies of signals output from two VCOs are mixed to form a desired output frequency, and the frequency of the output signal of one VCO compensates for the frequency of the output signal of the other VCO. With this configuration, CPU calculates only a division ratio for the PLL circuit in providing the desired output frequency, and therefore the execution steps of a control program for calculating the division ratio can be reduced to improve the processing speed.

However, the configuration of Patent Document 1 cannot make the transient response time of the PLL circuit shorter, even if the execution steps of the control program are reduced.

### SUMMARY OF THE INVENTION

Therefore, with the foregoing in mind, it is an object of the present invention to provide a PLL transient response control system that can reduce a transient response time when the frequency of a PLL circuit is changed with an external output signal.

A first PLL transient response control system of the present invention includes the following: a crystal oscillator for generating a reference frequency signal; a first PLL circuit for receiving the reference frequency signal output from the crystal oscillator; a second PLL circuit for receiving the reference frequency signal output from the crystal oscillator; and a mixer for mixing an oscillation frequency of the first PLL circuit and an oscillation frequency of the second PLL circuit. The first PLL circuit includes a first voltage-controlled oscillator, a first counter, a first phase comparator, and a first low-pass filter. The first voltage-controlled oscillator acts so that the oscillation frequency increases as a control voltage increases. The first counter divides the frequency of an output signal of the first voltage-controlled oscillator at a variable division ratio. The first phase comparator makes a phase comparison between an output signal of the first counter and the reference frequency signal. The first low-pass filter generates a feedback voltage from an output signal of the first phase comparator and applies the feedback voltage to the first voltage-controlled oscillator as the control voltage. The second PLL circuit includes a second voltage-controlled oscillator, a second counter, a second phase comparator, and a second low-pass filter. The second voltage-controlled oscillator acts so that the oscillation frequency decreases as a control voltage increases. The second counter divides the frequency of an output signal of the second voltage-controlled oscillator at a variable division ratio. The second phase comparator makes a phase comparison between an output signal of the second counter and the reference frequency signal. The second low-pass filter generates a feedback voltage from an output signal of the second phase comparator and applies the feedback voltage to the second voltage-controlled oscillator as the control voltage. The feedback voltage applied to the first voltage-controlled oscillator is added to the feedback voltage applied to the second voltage-controlled oscillator.

A second PLL transient response control system of the present invention includes the following: a crystal oscillator for generating a reference frequency signal; a third PLL circuit for receiving the reference frequency signal output from the crystal oscillator; a fourth voltage-controlled oscillator to which a control voltage output from the third PLL circuit is applied; and a mixer for mixing an oscillation frequency of the third PLL circuit and an oscillation frequency of the fourth voltage-controlled oscillator. The third PLL circuit includes a third voltage-controlled oscillator, a third counter, a third phase comparator, and a third low-pass filter. The third voltage-controlled oscillator acts so that the oscillation frequency increases as a control voltage increases. The third counter divides the frequency of an output signal of the third voltage-controlled oscillator at a variable division ratio. The third phase comparator makes a phase comparison between an output signal of the third counter and the reference frequency signal. The third low-pass filter generates a feedback voltage from an output signal of the third phase comparator and applies the feedback voltage to the third voltage-controlled oscillator as the control voltage. The fourth voltage-controlled oscillator acts so that the oscillation frequency decreases as the control voltage increases. The feedback voltage applied to the third voltage-controlled oscillator is applied to the fourth voltage-controlled oscillator.

A first communication system of the present invention includes a PLL transient response control system. The PLL transient response control system includes the following: a crystal oscillator for generating a reference frequency signal; a first PLL circuit for receiving the reference frequency signal output from the crystal oscillator; a second PLL circuit for receiving the reference frequency signal output from the crystal oscillator; a first mixer for mixing an oscillation frequency of the first PLL circuit and an oscillation frequency of the second PLL circuit; a second mixer for mixing an output signal of the first mixer and a radio frequency signal; a low-pass filter for converting an output signal of the second mixer into a signal for a direct conversion system; and a band-pass filter for converting an output signal of the second mixer into a signal for a low-IF system. The first PLL circuit includes a first voltage-controlled oscillator, a first counter, a first phase comparator, and a first low-pass filter. The first voltage-controlled oscillator acts so that the oscillation frequency increases as a control voltage increases. The first counter divides the frequency of an output signal of the first voltage-controlled oscillator at a variable division ratio. The first phase comparator makes a phase comparison between an output signal of the first counter and the reference frequency signal. The first low-pass filter generates a feedback voltage from an output signal of the first phase comparator and applies the feedback voltage to the first voltage-controlled oscillator as the control voltage. The second PLL circuit includes a second voltage-controlled oscillator, a second counter, a second phase comparator, and a second low-pass filter. The second voltage-controlled oscillator acts so that the oscillation frequency decreases as a control voltage increases. The second counter divides the frequency of an output signal of the second voltage-controlled oscillator at a variable division ratio. The second phase comparator makes a phase comparison between an output signal of the second counter and the reference frequency signal. The second low-pass filter generates a feedback voltage from an output signal of the second phase comparator and applies the feedback voltage to the second voltage-controlled oscillator as the control voltage.

A second communication system of the present invention includes a PLL transient response control system. The PLL transient response control system includes the following: a crystal oscillator for generating a reference frequency signal; a first PLL circuit for receiving the reference frequency signal output from the crystal oscillator; a second PLL circuit for receiving the reference frequency signal output from the crystal oscillator; a first mixer for mixing an oscillation frequency of the first PLL circuit and an oscillation frequency of the second PLL circuit; a first divider for dividing the frequency of an output signal of the first mixer by n; a second mixer for mixing an output signal of the first mixer and a radio frequency signal; a band-pass filter for transmitting only a signal in a predetermined frequency band of an output signal of the second mixer; and a third mixer for mixing an output signal of the first divider and the signal through the band-pass filter to output a signal for a superheterodyne system. The first PLL circuit includes a first voltage-controlled oscillator, a first counter, a first phase comparator, and a first low-pass filter. The first voltage-controlled oscillator acts so that the oscillation frequency increases as a control voltage increases. The first counter divides the frequency of an output signal of the first voltage-controlled oscillator at a variable division ratio. The first phase comparator makes a phase comparison between an output signal of the first counter and the reference frequency signal. The first low-pass filter generates a feedback voltage from an output signal of the first phase comparator and applies the feedback voltage to the first voltage-controlled oscillator as the control voltage. The second PLL circuit includes a second voltage-controlled oscillator, a second counter, a second phase comparator, and a second low-pass filter. The second voltage-controlled oscillator acts so that the oscillation frequency decreases as a control voltage increases. The second counter divides the frequency of an output signal of the second voltage-controlled oscillator at a variable division ratio. The second phase comparator makes a phase comparison between an output signal of the second counter and the reference frequency signal. The second low-pass filter generates a feedback voltage from an output signal of the second phase comparator and applies the feedback voltage to the second voltage-controlled oscillator as the control voltage.

A third communication system of the present invention includes a PLL transient response control system. The PLL transient response control system includes the following: a crystal oscillator for generating a reference frequency signal; a first PLL circuit for receiving the reference frequency signal output from the crystal oscillator; a second PLL circuit for receiving the reference frequency signal output from the crystal oscillator; a first mixer for mixing an oscillation frequency of the first PLL circuit and an oscillation frequency of the second PLL circuit; a second divider for dividing the frequency of an output signal of a first voltage-controlled oscillator by m; a second mixer for mixing an output signal of the first mixer and a radio frequency signal; a band-pass filter for transmitting only a signal in a predetermined frequency band of an output signal of the second mixer; and a third mixer for mixing an output signal of the second divider and the signal through the band-pass filter to output a signal for superheterodyne system. The first PLL circuit includes the first voltage-controlled oscillator, a first counter, a first phase comparator, and a first low-pass filter. The first voltage-controlled oscillator acts so that the oscillation frequency increases as a control voltage increases. The first counter divides the frequency of an output signal of the first voltage-controlled oscillator at a variable division ratio. The first phase comparator makes a phase comparison between an output signal of the first counter and the reference frequency signal. The first low-pass filter generates a feedback voltage from an output signal of the first phase comparator and applies the feedback voltage to the first voltage-controlled oscillator as the control voltage. The second PLL circuit includes a second voltage-controlled oscillator, a second counter, a second phase comparator, and a second low-pass filter. The second voltage-controlled oscillator acts so that the oscillation frequency decreases as a control voltage increases. The second counter divides the frequency of an output signal of the second voltage-controlled oscillator at a variable division ratio. The second phase comparator makes a phase comparison between an output signal of the second counter and the reference frequency signal. The second low-pass filter generates a feedback voltage from an output signal of the second phase comparator and applies the feedback voltage to the second voltage-controlled oscillator as the control voltage.

### BRIEF DESCRIPTION OF THE DRAWINGS

FIG. 1 is a block diagram showing a PLL transient response control system of Embodiment 1 of the present invention.

FIG. 2 is a graph showing an operation of the PLL transient response control system in FIG. 1.

FIG. 3 is a block diagram showing a PLL transient response control system of Embodiment 2 of the present invention.

FIG. 4 is a graph showing an operation of the PLL transient response control system in FIG. 3.

FIG. 5 is a block diagram showing a PLL transient response control system of Embodiment 3 of the present invention.

FIG. 6 is a block diagram showing a PLL transient response control system of Embodiment 4 of the present invention.

FIG. 7 is a block diagram showing a PLL transient response control system of Embodiment 4 of the present invention.

FIG. 8 is a block diagram showing a PLL transient response control system of Embodiment 5 of the present invention.

FIG. 9 is a block diagram showing a PLL transient response control system of Embodiment 6 of the present invention.

FIG. 10 is a block diagram showing a PLL transient response control system of Embodiment 7 of the present invention.

FIG. 11 is a block diagram showing a PLL transient response control system of Embodiment 8 of the present invention.

FIG. 12 is a block diagram showing a modified example of the PLL transient response control system of Embodiment 8 of the present invention.

FIG. 13 is a block diagram showing a conventional PLL system.

FIG. 14 is a graph showing an operation of the conventional PLL system.

### DETAILED DESCRIPTION OF THE INVENTION

In the PLL transient response control system according to a preferred embodiment of the present invention, the operation of adding the feedback voltage applied to the first voltage-controlled oscillator to the feedback voltage applied to the second voltage-controlled oscillator may be stopped at the time of completion of a transient response of the first PLL circuit. With this configuration, no feedback voltage is applied to the second voltage-controlled oscillator after the transient response is completed, and the first PLL circuit is in the steady state. Therefore, it is possible to avoid modulation of the second voltage-controlled oscillator due to a steady-state error of the first PLL circuit, resulting in a higher C/N ratio.

In the PLL transient response control system according to another preferred embodiment of the present invention, a f/V characteristic regulator may be provided and regulate the f/V characteristics of the second voltage-controlled oscillator so that the f/V characteristics of the first voltage-controlled oscillator and the f/V characteristics of the second voltage-controlled oscillator are oriented in opposite directions to each other and have substantially the same absolute values. With this configuration, when the f/V characteristics (absolute values) of the first and second voltage-controlled oscillators fluctuate relatively due to manufacturing variations or the like, those values are adjusted to be the same, so that frequency variations caused by the PLL transient response can be canceled out appropriately.

The PLL transient response control system according to yet another preferred embodiment of the present invention may include a divider for dividing the frequency of an output signal of the mixer by n, and a divider for dividing the frequency of an output signal of either of the first and second voltage-controlled oscillators by m. With this configuration, frequency variations caused by the transient response of output signals of each of the dividers can be reduced to 1/n or 1/m.

In the PLL transient response control system and the communication system of the present invention, the frequency variations in outputs of the first and second voltage-controlled oscillators, which occur after setting the division ratio of each counter with an external control signal for the transition to a desired frequency, cancel each other out, and thus the lock-up time of a PLL circuit can be reduced. For TDMA that has been used widely as a mode of the communication system, even if the base stations are out of synchronization, the lock of the PLL circuit is completed during the period of a communication slot, thereby achieving a good transmission rate.

### EMBODIMENT 1

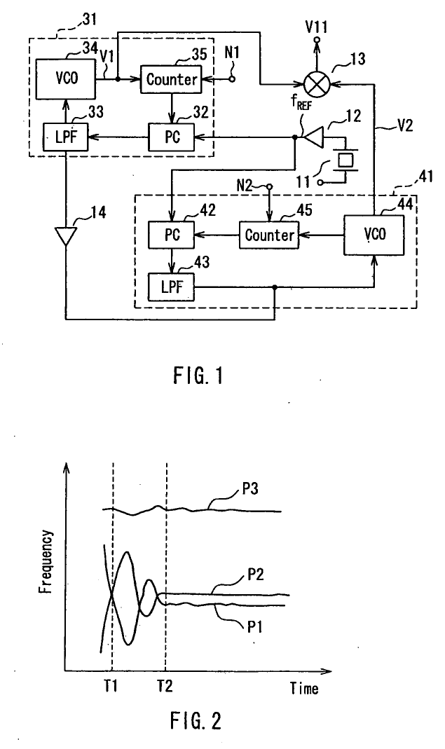

FIG. 1 is a block diagram showing a PLL transient response control system of Embodiment 1 of the present invention. FIG. 2 is a graph showing the frequency characteristics of each part in the PLL transient response control system of FIG. 1.

The PLL transient response control system includes a crystal oscillator 11, a first buffer 12, a mixer 13, a second buffer 14, a first PLL circuit 31, and a second PLL circuit 41. The first PLL circuit 31 includes a first phase comparator 32, a first LPF 33, a first VCO 34, and a first counter 35 and forms a closed loop. The second PLL circuit 41 includes a second phase comparator 42, a second LPF 43, a second VCO 44, and a second counter 45 and forms a closed loop. The output of the first buffer 12 is supplied to the first phase comparator 32 and the second phase comparator 42. The output of the first LPF 33 is supplied to the second buffer 14. The output of the second buffer 14 is supplied to the second VCO 44. The output of the first VCO 34 is supplied to the first counter 35 and the mixer 13. The output of the second VCO 44 is supplied to the second counter 45 and the mixer 13.

The first VCO 34 increases in frequency as a control voltage increases. The second VCO 44 decreases in frequency as a control voltage increases. The first counter 35 divides the frequency of an output signal of the first VCO 34. The second counter 45 divides the frequency of an output signal of the second VCO 44. The division ratios of the first and second counters 35, 45 can be set with external control signals N1 and N2 (variable division ratios), respectively.

The operation of the PLL transient response control system will be described below.

A signal of a reference frequency f_{REF} generated by a reference frequency generator including the crystal oscillator 11 and the first buffer 12 is input to the first phase comparator 32 and to the second phase comparator 42.

The first phase comparator 32 makes a phase comparison between an output signal of the first counter 35 and the signal of the reference frequency f_{REF} and outputs a phase error signal as a result of the comparison to the first LPF 33. The first LPF 33 removes a high frequency component from the phase error signal provided by the first phase comparator 32. An output signal of the first LPF 33 is input to the first VCO 34 and to the second buffer 14. The output signal of the first LPF 33 is a direct-current voltage that serves not only as a feedback voltage applied to the first VCO 34, but also as a feedback voltage applied to the second VCO 44 via the second buffer 14 that transmits only an alternating-current component.

The second phase comparator 42 makes a phase comparison between an output signal of the second counter 45 and the signal of the reference frequency f_{REF} and outputs a phase error signal as a result of the comparison to the second LPF 43. The second LPF 43 removes a high frequency component from the phase error signal provided by the second phase comparator 42. An output signal of the second LPF 43 is input to the second VCO 44. The output signal of the second LPF 43 is a direct-current voltage that serves as a feedback voltage applied to the second VCO 44.

In the above circuitry of the PLL transient response control system, the second VCO 44 has been locked previously at an intermediate frequency with an external control signal. When data is set to the first counter 35 with an external control signal so as to obtain a desired frequency, the first VCO 34 starts a transient response, and the transient response voltage is applied to the second VCO 44 via the second buffer 14.

The oscillation frequencies of the first VCO 34 and the second VCO 44 are either increased or decreased with a rise in one feedback voltage. For example, if the first VCO 34 increases in frequency f_{V1}, then the second VCO 44 decreases in frequency f_{V2}. Therefore, when an output signal V1 of the first VCO 34 and an output signal V2 of the second VCO 44 are synthesized (multiplied) by the mixer 13 to add the frequencies of the two signals (f_{V1}+f_{V2}), a frequency variation in an output signal V11 of the mixer 13 becomes small, as represented by P3 in FIG. 2. Thus, the end of the PLL lock-up time is moved up from T2 to T1, so that the lock-up time can be reduced.

In this embodiment, the first PLL circuit 31 includes the first VCO 34 that increases in oscillation frequency as the control voltage increases, the second PLL circuit 41 includes the second VCO 44 that decreases in oscillation frequency as the control voltage increases, the alternate-current component output from the first PLL circuit 31 is fed back to the second PLL circuit 41, and the output signal V1 of the first VCO 34 and the output signal V2 of the second VCO 44 are synthesized by the mixer 13. This configuration allows the frequency variations that occur in the first PLL circuit 31 and the second PLL circuit 41 during the transient response to cancel each other out, and thus can reduce the transient response time.

The second PLL circuit 41 including the second VCO 44 to which the feedback voltage is applied has been locked previously at an intermediate frequency with an external control signal, and the transient response of the second PLL circuit 41 needs to be completed. The first PLL circuit 31 including the first VCO 34 acquires a desired frequency by setting the division ratio with an external control signal, and subsequently the transient response of the first PLL circuit 31 is started.

### EMBODIMENT 2

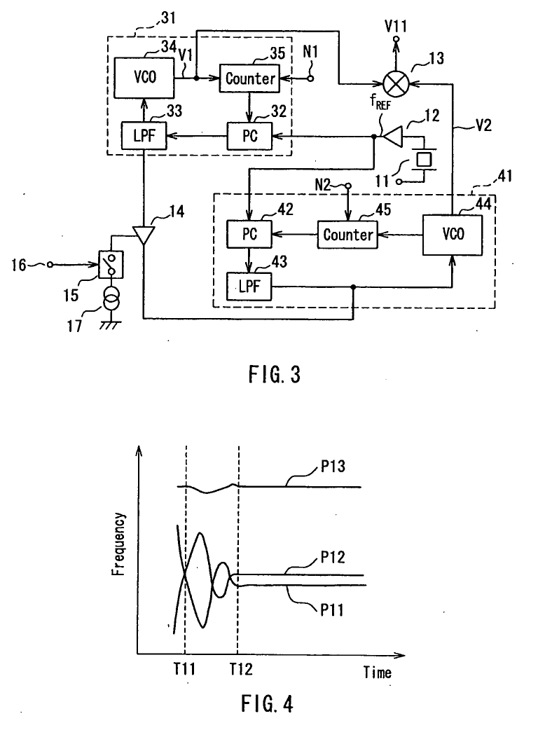

FIG. 3 is a block diagram showing a PLL transient response control system of Embodiment 2 of the present invention. FIG. 4 is a graph showing the frequency characteristics of each part in the PLL transient response control system of FIG. 3. In FIG. 3, the same components as those in FIG. 1 are denoted by the same reference numerals, and the explanation will not be repeated. This PLL transient response control system further includes a switch 15 for stopping the operation of the second buffer 14, a terminal 16 for receiving a lock detection signal, and a current source 17 in addition to the configuration in FIG. 1.

When a lock detection signal is input to the terminal 16, the switch 15 is turned off, and then a current generated by the current source 17 does not flow into a control terminal of the second buffer 14 through the switch 15. The second buffer 14 stops operating while no current is flowing into the control terminal.

The PLL circuit generally outputs a lock detection signal upon completion of the transient response. Therefore, by using the lock detection signal output from the first PLL circuit 31 at the time the transient response is completed, the PLL transient response control system of this embodiment interrupts the feedback voltage from the first LPF 33 to the second VCO 44.

As shown in FIG. 3, the switch 15 is turned off in response to the lock detection signal input to the terminal 16 and prevents the flow of a current generated by the current source 17 into the control terminal of the second buffer 14. Accordingly, no current flows into the control terminal, and the second buffer 14 stops operating.

As shown in FIG. 4, the operation of the second buffer 14 is stopped and the feedback voltage from the first LPF 33 to the second VCO 44 is interrupted at the timing T12 when the transient response of the first PLL circuit 31 is completed. Consequently, the steady-state error of the first PLL circuit 31 is not added to the feedback voltage applied to the second VCO 44, which can improve the C/N ratio of the output signal V11 of the mixer 13 after the timing T12.

Like Embodiment 1, during the transient response represented by the period between T11 and T12 in FIG. 4, the feedback voltage is applied not only to the first VCO 34, but also to the second VCO 44 via the second buffer 14. Therefore, the frequency variations that occur in the first PLL circuit 31 and the second PLL circuit 41 during the transient response can cancel each other out, as represented by P13 in FIG. 4. Thus, the end of the PLL lock-up time is moved up from T12 to T11, so that the transient response time can be reduced.

As described above, this embodiment can reduce the lock-up time and improve the C/N ratio of the output signal V11 of the mixer 13.

### EMBODIMENT 3

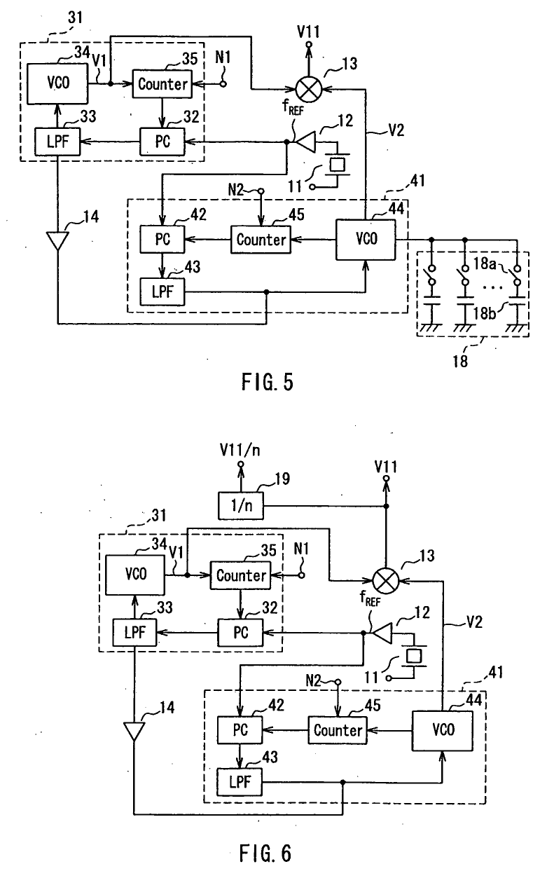

FIG. 5 is a block diagram showing a PLL transient response control system of Embodiment 3 of the present invention. In FIG. 5, the same components as those in FIG. 1 are denoted by the same reference numerals, and the explanation will not be repeated. This PLL transient response control system further includes a f/V characteristic regulator 18 in addition to the configuration in FIG. 1.

The voltage-controlled oscillator (VCO) generally includes a coil, a varactor diode, a capacitor with a fixed capacitance, etc. The f/V characteristics (the relationship between the oscillation frequency and the control voltage) of the VCO can vary due to characteristic variations of each circuit element. To reduce a frequency variation in the output signal V11 of the mixer 13 during the transient response of the first PLL circuit 31, it is desirable that the frequencies of the first VCO 34 and the second VCO 44 are changed in opposite directions to each other with respect to their feedback voltages, and the absolute value of the change in frequency of the first VCO 34 is substantially the same as that of the change in frequency of the second VCO 44. Therefore, the PLL transient response control system in this embodiment uses the f/V characteristic regulator 18 to regulate the f/V characteristics of the second VCO 44.

As shown in FIG. 5, the f/V characteristic regulator 18 includes a plurality of units, each of which is composed of a switch 18a and a capacitor 18b connected in series, and these units are connected in parallel. One or more than one switch 18a is turned on/off to increase/decrease the capacitance of the capacitor in the second VCO 44, and the f/V characteristics of the second VCO 44 can be changed as desired.

In this embodiment, since the f/V characteristic regulator 18 can increase or decrease the capacitance of the capacitor in the second VCO 44, the f/V characteristic variations of the second VCO 44 can be reduced. Thus, it is possible to change the frequencies of the first VCO 34 and the second VCO 44 in opposite directions to each other with respect to their feedback voltages, and also to make the absolute value of the change in frequency of the first VCO 34 substantially the same as that of the change in frequency of the second VCO 44.

### EMBODIMENT 4

Embodiment 4 uses a divider to suppress a frequency variation.

FIG. 6 is a block diagram showing a first configuration of a PLL transient response control system of Embodiment 4 of the present invention. In FIG. 6, the same components as those in FIG. 1 are denoted by the same reference numerals, and the explanation will not be repeated. This PLL transient response control system further includes a divider 19 for dividing the frequency of the output signal V11 of the mixer 13 by n (n is an integer) in addition to the configuration in FIG. 1.

The divider 19 divides the frequency of the output signal V11 of the mixer 13 having a fast transient response by n, and thus can produce a signal of a desired frequency. Accordingly, the frequency variations that occur in the first PLL circuit 31 and the second PLL circuit 41 during the transient response can be reduced to 1/n.

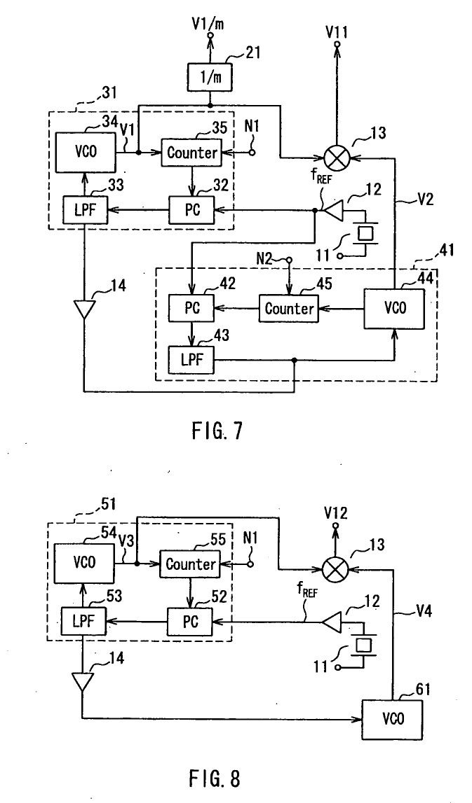

FIG. 7 is a block diagram showing a second configuration of a PLL transient response control system of Embodiment 4 of the present invention. In FIG. 7, the same components as those in FIG. 1 are denoted by the same reference numerals, and the explanation will not be repeated. This PLL transient response control system further includes a divider 21 for dividing the frequency of the output signal V1 of the first VCO 34 by m (m is an integer) in addition to the configuration in FIG. 1.

The output signal V1 of the first VCO 34 is input to the divider 21 during the transient response. Therefore, a frequency variation in the output signal V1 of the first VCO 34 can be reduced to 1/m, although the transient response of the output signal of the divider 21 is slower compared to the case where the output signal (V1+V2) of the mixer 13 having a fast transient response is input, as shown in FIG. 6.

This embodiment can reduce the frequency variations that occur in the first PLL circuit 31 and the second PLL circuit 41 during the transient response to 1/n or 1/m.

Moreover, the configuration in FIG. 7 can reduce the circuit size as well as the power consumption. In other words, although the frequency outputs of the dividers 19, 21 are about the same, the frequency f_{V1} of the first VCO 34 (or the frequency f_{V2} of the second VCO 44) is lower than the frequency (f_{V1}+f_{V2}) of the output signal V11 of the mixer 13. Thus, the divider 21 (FIG. 7) can have a smaller circuit size and less power consumption than at least the divider 19 (FIG. 6).

In FIG. 7, the divider 21 divides the frequency of the output signal V1 of the first VCO 34, but it also can divide the frequency of the output signal V2 of the second VCO 44.

The PLL transient response control system may include both of the dividers 19, 21.

### EMBODIMENT 5

FIG. 8 is a block diagram showing a PLL transient response control system of Embodiment 5 of the present invention. In FIG. 8, the same components as those in FIG. 1 are denoted by the same reference numerals, and the explanation will not be repeated.

The PLL transient response control system includes a crystal oscillator 11, a first buffer 12, a mixer 13, a second buffer 14, a third PLL circuit 51, and a fourth VCO 61. The third PLL circuit 51 includes a third phase comparator 52, a third LPF 53, a third VCO 54, and a third counter 55 and forms a closed loop. The output of the first buffer 12 is supplied to the third phase comparator 52. The output of the third LPF 53 is supplied to the second buffer 14. The output of the second buffer 14 is supplied to the fourth VCO 61. The output of the third VCO 54 is supplied to the third counter 55 and the mixer 13. The output of the fourth VCO 61 is supplied to the mixer 13.

The third VCO 54 increases in frequency as a control voltage increases. The fourth VCO 61 decreases in frequency as a control voltage increases. The third counter 55 divides the frequency of an output signal of the third VCO 54. The division ratio of the third counter 55 can be set with an external control signal N1 (a variable division ratio). A signal of a reference frequency f_{REF} generated by a reference frequency generator including the crystal oscillator 11 and the first buffer 12 is input to the third phase comparator 52. The third phase comparator 52 makes a phase comparison between an output signal of the third counter 55 and the signal of the reference frequency f_{REF} and outputs a phase error signal as a result of the comparison to the third LPF 53. The third LPF 53 removes a high frequency component from the phase error signal provided by the third phase comparator 52. An output signal of the third LPF 53 serves as a feedback voltage applied to the third VCO 54. The output signal of the third LPF 53 also is input to the fourth VCO 61 via the second buffer 14 that transmits only an alternating-current component. An output signal V3 of the third VCO 54 and an output signal V4 of the fourth VCO 61 are synthesized (multiplied) by the mixer 13 to provide an output signal V12. At this time, the frequency fv3 of the output signal V3 and the frequency f_{V4} of the output signal V4 are added (f_{V3}+f_{V4}).

The PLL transient response control system in Embodiment 6 differs from Embodiment 1 in that the fourth VCO 61 is not controlled by the PLL, i.e., a second PLL circuit including the fourth VCO 61 is not provided. When data is set to the third counter 55 with an external control signal so as to obtain a desired frequency, the third VCO 54 starts a transient response, and the transient response voltage is applied to the fourth VCO 61 via the second buffer 14 that transmits only an alternating-current component. The oscillation frequencies of the third VCO 54 and the fourth VCO 61 are increased or decreased in opposite directions to each other with a rise in one feedback voltage. For example, if the third VCO 54 increases in frequency, then the fourth VCO 61 decreases in frequency.

Therefore, when the output signal V3 of the third VCO 54 and the output signal V4 of the fourth VCO 61 are synthesized (multiplied) by the mixer 13 to add the frequencies of the two signals (f_{V3}+f_{V4}), a frequency variation in the output signal V12 of the mixer 13 becomes small, and the lock-up time can be reduced.

### EMBODIMENT 6

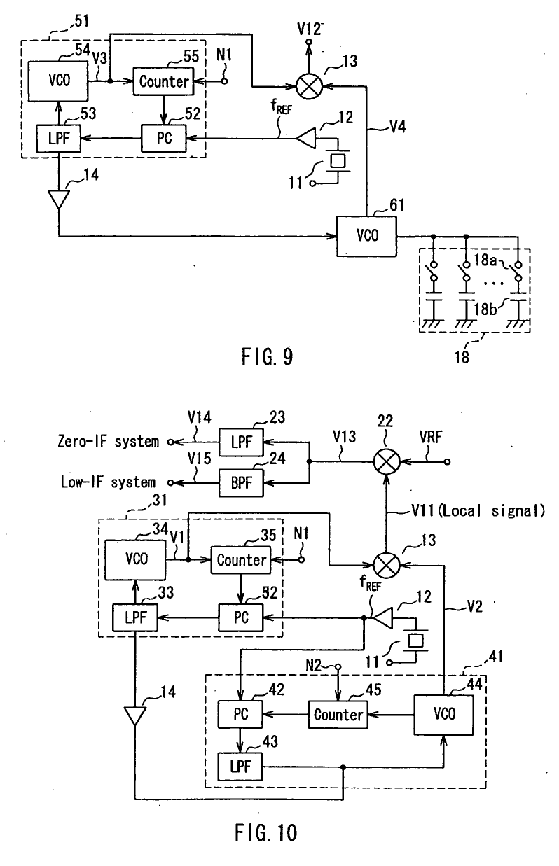

FIG. 9 is a block diagram showing a PLL transient response control system of Embodiment 6 of the present invention. In FIG. 9, the same components as those in FIG. 8 are denoted by the same reference numerals, and the explanation will not be repeated. This PLL transient response control system further includes a f/V characteristic regulator 18 for regulating the f/V characteristics of the fourth VCO 61 in addition to the configuration in FIG. 8.

The voltage-controlled oscillator (VCO) generally includes a coil, a varactor diode, a capacitor with a fixed capacitance, etc. The f/V characteristics (the relationship between the oscillation frequency and the control voltage) of the VCO can vary due to characteristic variations of each circuit element. To reduce a frequency variation in the output signal V12 of the mixer 13 during the transient response of the third PLL circuit 51, it is desirable that the frequencies of the third VCO 54 and the fourth VCO 61 are changed in opposite directions to each other with respect to the feedback voltage, and the absolute value of the change in frequency of the third VCO 54 is substantially the same as that of the change in frequency of the fourth VCO 61. Therefore, the PLL transient response control system in this embodiment uses the f/V characteristic regulator 18 to regulate the f/V characteristics of the fourth VCO 61.

As shown in FIG. 9, the f/V characteristic regulator 18 includes a plurality of units, each of which is composed of a switch 18a and a capacitor 18b connected in series, and these units are connected in parallel. One or more than one switch 18a is turned on/off to increase/decrease the capacitance of the capacitor in the fourth VCO 61, and the f/V characteristics of the fourth VCO 61 can be changed as desired.

In this embodiment, since the f/V characteristic regulator 18 can increase or decrease the capacitance of the capacitor in the fourth VCO 61, the f/V characteristic variations of the fourth VCO 61 can be reduced. Thus, it is possible to change the frequencies of the third VCO 54 and the fourth VCO 61 in opposite directions to each other with respect to the feedback voltage, and also to make the absolute value of the change in frequency of the third VCO 54 substantially the same as that of the change in frequency of the fourth VCO 61.

### EMBODIMENT 7

FIG. 10 is a block diagram showing a PLL transient response control system of Embodiment 7 of the present invention. In FIG. 10, the same components as those in FIG. 1 are denoted by the same reference numerals, and the explanation will not be repeated. This PLL transient response control system further includes a mixer 22, a LPF 23, and a BPF (band-pass filter) 24 in addition to the configuration in FIG. 1.

The local signal V11 output from the mixer 13 and a signal VRF of a radio frequency are input to the mixer 22. The mixer 22 mixes the frequencies of the two input signals and outputs a signal V13 (IF signal) of an intermediate frequency. The LPF 23 removes a high frequency component from the output signal V13 of the mixer 22 and outputs a signal V14. The BPF 24 outputs a signal V15 in a predetermined intermediate band of the output signal V13 of the mixer 22.

The operation of the PLL transient response control system will be described below.

For example, GSM (global system for mobile communications) employing TDMA generally uses a receiving system such as a direct conversion system (zero-IF system) or low-IF system. In the direct conversion system, the relationship expressed as

Local signal=Radio frequency is established. The output signal V13 of the mixer 22 is input to the LPF 23. The LPF 23 removes the high frequency component from the output signal V13 and rejects an undesired signal.

In the low-IF system, the relationship expressed as

Local signal=Radio frequency−IF frequency is established. The output signal V13 of the mixer 22 is input to the BPF 24. The BPF 24 transmits only a signal in a predetermined band of the output signal V13 and rejects an undesired signal. The BPF 24 can shift the passband to a low frequency band, and thus can be used in both the direct conversion system and the low-IF system. Accordingly, it is relatively easy to form the BPF 24 on a semiconductor chip.

The PLL circuit has exacting standards for the C/N ratio of the local signal. In the general PLL circuit, there is a trade-off between the C/N ratio and the lock-up time. Therefore, if the C/N ratio is improved, the lock-up time becomes longer, and if the lock-up time is made shorter, the C/N ratio is degraded.

In contrast, Embodiment 7 can reduce the lock-up time of the first PLL circuit 31 including the first VCO 34 and also can improve the C/N ratio. That is, the C/N ratio is improved while the lock-up time of the first PLL circuit 31 is reduced by synthesizing (multiplying) the output frequency f_{V1} of the first VCO 34 and the output frequency f_{V2} of the second VCO 44 with the mixer 13.

### EMBODIMENT 8

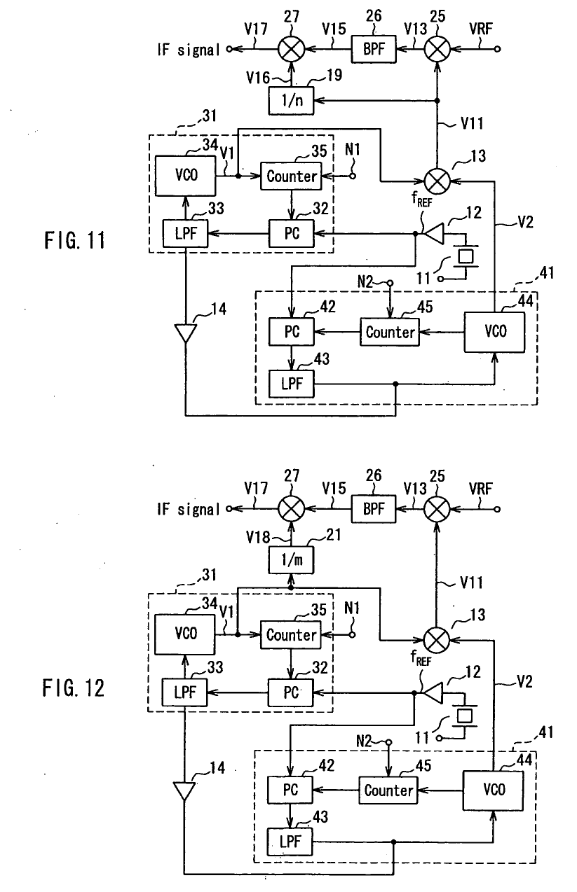

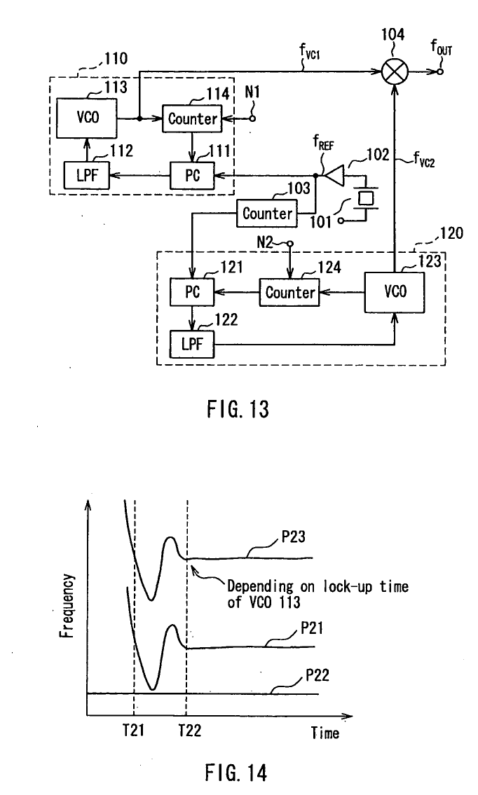

FIG. 11 is a block diagram showing a PLL transient response control system of Embodiment 8 of the present invention. In FIG. 11, the same components as those in FIG. 1 are denoted by the same reference numerals, and the explanation will not be repeated. This PLL transient response control system further includes a divider 19, a mixer 25, a BPF 26, and a mixer 27 in addition to the configuration in FIG. 1.

The divider 19 divides the frequency of the output signal V11 of the mixer 13 by n and outputs a signal V16. The local signal V11 output from the mixer 13 and a signal VRF of a ratio frequency are input to the mixer 25. The mixer 25 mixes the frequencies of the two input signals and outputs a signal V13 (IF signal) of an intermediate frequency. The BPF 26 outputs a signal V15 in a predetermined intermediate band of the output signal V13 of the mixer 25. The mixer 27 mixes the output signal V16 of the divider 19 and the output signal V15 of the BPF 26 and generates a signal V17.

The operation of the PLL transient response control system will be described below.

A superheterodyne system is well known as a general communication system. The superheterodyne system requires two local signals and can increase a first intermediate frequency f_{IN1} compared to the low-IF system, as described in Embodiment 7. This makes it easy for the superheterodyne system to reject an image signal.

In Embodiment 8, the output signal V11 (local signal) of the mixer 13 is used to generate a signal of the first intermediate frequency f_{IN1}. Moreover, the frequency of the output signal V11 (local signal) of the mixer 13 is divided by n with the divider 19, and the resultant signal V16 is used to generate a signal of a second intermediate frequency f_{IN2}.

The first intermediate frequency f_{IN1} generated by the mixer 25 is expressed as
f_{IN1}=f_{R}−f_{V11}
where f_{R} is the radio frequency and f_{V11} is the frequency of the output signal V11. The second intermediate frequency f_{IN2} generated by the mixer 27 is expressed as
f_{IN2}=(f_{R}−f_{V11})±f_{V11}/n
where n is the division ratio of the divider 19.

The PLL transient response control system in Embodiment 8 may be configured as shown in FIG. 12. In the configuration of FIG. 12, a divider 21 divides the frequency of the output signal V1 of the first VCO 34 by m and outputs a signal V18 to the mixer 27. The mixer 27 mixes the output signal V18 of the divider 21 and the output signal V15 of the BPF 26 and generates a signal V17 of the second intermediate frequency f_{IN2}.

The second intermediate frequency f_{IN2} generated by the mixer 27 is expressed as
f_{IN2}=(f_{R}−f_{V11})±f_{V1}/m
where f_{R} is the radio frequency, f_{V1} is the frequency of the output signal V1, f_{V11} is the frequency of the output signal V11, and m is the division ratio of the divider 21.

In this configuration, the frequency of the output signal V2 of the second VCO 44 may be divided by m with the divider 21, and the resultant signal may be used to generate a signal of the second intermediate frequency f_{IN2}. The second intermediate frequency fIN2 generated by the mixer 25 is expressed as
f_{IN2}=(f_{R}−f_{V11})±f_{V2}/m
where f_{R} is the radio frequency, f_{V2} is the frequency of the output signal V2, f_{V11} is the frequency of the output signal V11, and m is the division ratio of the divider 21.

In either case, the frequencies of the first VCO 34 and the second VCO 44 need to be set so as to prevent a spurious signal caused by the first VCO 34 and the second VCO 44 from occurring in a desired band. Since variations in each of the frequencies f_{V11}/n, f_{V1}/m, and f_{V2}/m during the transient response are reduced, the lock-up time can be reduced as a whole.

As described above, the PLL transient response control system of the present invention is useful for a semiconductor integrated circuit device that constitutes a PLL circuit, and particularly for a TDMA communication system.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A PLL transient response control system comprising:
a crystal oscillator for generating a reference frequency signal;
a first PLL circuit for receiving the reference frequency signal output from the crystal oscillator;
a second PLL circuit for receiving the reference frequency signal output from the crystal oscillator; and
a mixer for mixing an oscillation frequency of the first PLL circuit and an oscillation frequency of the second PLL circuit, wherein the first PLL circuit comprises:
a first voltage-controlled oscillator that acts so that the oscillation frequency increases as a control voltage increases;
a first counter that divides a frequency of an output signal of the first voltage-controlled oscillator at a variable division ratio;
a first phase comparator that makes a phase comparison between an output signal of the first counter and the reference frequency signal; and
a first low-pass filter that generates a feedback voltage from an output signal of the first phase comparator and applies the feedback voltage to the first voltage-controlled oscillator as the control voltage, wherein the second PLL circuit comprises:
a second voltage-controlled oscillator that acts so that the oscillation frequency decreases as a control voltage increases;
a second counter that divides a frequency of an output signal of the second voltage-controlled oscillator at a variable division ratio;
a second phase comparator that makes a phase comparison between an output signal of the second counter and the reference frequency signal; and
a second low-pass filter that generates a feedback voltage from an output signal of the second phase comparator and applies the feedback voltage to the second voltage-controlled oscillator as the control voltage, and wherein the feedback voltage applied to the first voltage-controlled oscillator is added to the feedback voltage applied to the second voltage-controlled oscillator.

2. The PLL transient response control system according to claim 1, wherein the operation of adding the feedback voltage applied to the first voltage-controlled oscillator to the feedback voltage applied to the second voltage-controlled oscillator is stopped at the time of completion of a transient response of the first PLL circuit.

3. The PLL transient response control system according to claim 1, further comprising a f/V characteristic regulator, wherein the f/V characteristic regulator regulates f/V characteristics of the second voltage-controlled oscillator so that f/V characteristics of the first voltage-controlled oscillator and the f/V characteristics of the second voltage-controlled oscillator are oriented in opposite directions to each other and have substantially the same absolute values.

4. The PLL transient response control system according to claim 1, further comprising:
a first divider for dividing a frequency of an output signal of the mixer by n; and
a second divider for dividing a frequency of an output signal of either of the first and second voltage-controlled oscillators by m.

5. A PLL transient response control system comprising:
a crystal oscillator for generating a reference frequency signal;
a third PLL circuit for receiving the reference frequency signal output from the crystal oscillator;
a fourth voltage-controlled oscillator to which a control voltage output from the third PLL circuit is applied; and
a mixer for mixing an oscillation frequency of the third PLL circuit and an oscillation frequency of the fourth voltage-controlled oscillator, wherein the third PLL circuit comprises:
a third voltage-controlled oscillator that acts so that the oscillation frequency increases as a control voltage increases;
a third counter that divides a frequency of an output signal of the third voltage-controlled oscillator at a variable division ratio;
a third phase comparator that makes a phase comparison between an output signal of the third counter and the reference frequency signal; and
a third low-pass filter that generates a feedback voltage from an output signal of the third phase comparator and applies the feedback voltage to the third voltage-controlled oscillator as the control voltage, wherein the fourth voltage-controlled oscillator acts so that the oscillation frequency decreases as the control voltage increases, and wherein the feedback voltage applied to the third voltage-controlled oscillator is applied to the fourth voltage-controlled oscillator.

6. The PLL transient response control system according to claim 5, further comprising a f/V characteristic regulator,
wherein the f/V characteristic regulator regulators f/V characteristics of the fourth voltage-controlled oscillator so that f/V characteristics of the third voltage-controlled oscillator and the f/V characteristics of the fourth voltage-controlled oscillator are oriented in opposite directions to each other and have substantially the same absolute values.

7. A communication system comprising a PLL transient response control system,
the PLL transient response control system comprising:
a crystal oscillator for generating a reference frequency signal;
a first PLL circuit for receiving the reference frequency signal output from the crystal oscillator;
a second PLL circuit for receiving the reference frequency signal output from the crystal oscillator;
a first mixer for mixing an oscillation frequency of the first PLL circuit and an oscillation frequency of the second PLL circuit;
a second mixer for mixing an output signal of the first mixer and a radio frequency signal;
a low-pass filter for converting an output signal of the second mixer into a signal for a direct conversion system; and
a band-pass filter for converging an output signal of the second mixer into a signal for a low-IF system, wherein the first PLL circuit comprises:
a first voltage-controlled oscillator that acts so that the oscillation frequency increases as a control voltage increases;
a first counter that divides a frequency of an output signal of the first voltage-controlled oscillator at a variable division ratio;
a first phase comparator that makes a phase comparison between an output signal of the first counter and the reference frequency signal; and
a first low pass filter that generates a feedback voltage from an output signal of the first phase comparator and applies the feedback voltage to the first voltage-controlled oscillator as the control voltage, and wherein the second PLL circuit comprises:
a second voltage-controlled oscillator that acts so that the oscillation frequency decreases as a control voltage increases;
a second counter that divides a frequency of an output signal of the second voltage-controlled oscillator at a variable division ratio;
a second phase comparator that makes a phase comparison between an output signal of the second counter and the reference frequency signal; and
a second low-pass filter that generates a feedback voltage from an output signal of the second phase comparator and applies the feedback voltage to the second voltage-controlled oscillator as the control voltage.

8. A communication system comprising a PLL transient response control system,
the PLL transient response control system comprising:
a crystal oscillator for generating a reference frequency signal;
a first PLL circuit for receiving the reference frequency signal output from the crystal oscillator;
a second PLL circuit for receiving the reference frequency signal output from the crystal oscillator;
a first mixer for mixing an oscillation frequency of the first PLL circuit and an oscillation frequency of the second PLL circuit;
a first divider for dividing a frequency of an output signal of the first mixer by n;
a second mixer for mixing an output signal of the first mixer and a radio frequency signal;
a band-pass filter for transmitting only a signal in a predetermined frequency band of an output signal of the second mixer; and
a third mixer for mixing an output signal of the first divider and the signal through the band-pass filter to output a signal for a superheterodyne system,
wherein the first PLL circuit comprises:
a first voltage-controlled oscillator that acts so that the oscillation frequency increases as a control voltage increases;
a first counter that divides a frequency of an output signal of the first voltage-controlled oscillator at a variable division ratio;
a first phase comparator that makes a phase comparison between an output signal of the first counter and the reference frequency signal; and
a first low-pass filter that generates a feedback voltage from an output signal of the first phase comparator and applies the feedback voltage to the first voltage-controlled oscillator as the control voltage, and wherein the second PLL circuit comprises:
a second voltage-controlled oscillator that acts so that the oscillation frequency decreases as a control voltage increases;
a second counter that divides a frequency of an output signal of the second voltage-controlled oscillator at a variable division ratio;
a second phase comparator that makes a phase comparison between an output signal of the second counter and the reference frequency signal; and
a second low-pass filter that generates a feedback voltage from an output signal of the second phase comparator and applies the feedback voltage to the second voltage-controlled oscillator as the control voltage.

9. A communication system comprising a PLL transient response control system,
the PLL transient response control system comprising:
a crystal oscillator for generating a reference frequency signal;
a first PLL circuit for receiving the reference frequency signal output from the crystal oscillator;
a second PLL circuit for receiving the reference frequency signal output from the crystal oscillator;
a first mixer for mixing an oscillation frequency of the first PLL circuit and an oscillation frequency of the second PLL circuit;
a second divider for dividing a frequency of an output signal of a first voltage-controlled oscillator by m;
a second mixer for mixing an output signal of the first mixer and a radio frequency signal;
a band-pass filter for transmitting only a signal in a predetermined frequency band of an output signal of the second mixer; and
a third mixer for mixing an output signal of the second divider and the signal through the band-pass filter to output a signal for superheterodyne system,
wherein the first PLL circuit comprises:
the first voltage-controlled oscillator that acts so that the oscillation frequency increases as a control voltage increases;
a first counter that divides a frequency of an output signal of the first voltage-controlled oscillator at a variable division ratio;
a first phase comparator that makes a phase comparison between an output signal of the first counter and the reference frequency signal; and
a first low-pass filter that generates a feedback voltage from an output signal of the first phase comparator and applies the feedback voltage to the first voltage-controlled oscillator as the control voltage, and wherein the second PLL circuit comprises:
a second voltage-controlled oscillator that acts so that the oscillation frequency decreases as a control voltage increases;
a second counter that divides a frequency of an output signal of the second voltage-controlled oscillator at a variable division ratio;
a second phase comparator that makes a phase comparison between an output signal of the second counter and the reference frequency signal; and
a second low-pass filter that generates a feedback voltage from an output signal of the second phase comparator and applies the feedback voltage to the second voltage-controlled oscillator as the control voltage.
